(19) United States
(12) Patent Application Publication
(10) Pub. No.: US 2003/0090275 A1
(43) Pub. Date: May 15, 2003

(54) Determining a continuous-time transfer function of a system from sampled data measurements with application to disk drives

(75) Inventor: Petros A. Ioannou, Palos Verdes Estates, CA (US)

Correspondence Address: HOGAN & HARTSON L.L.P., 500 S. GRAND AVENUE, SUITE 1900, LOS ANGELES, CA, 90071-2611, US

(73) Assignee: Acorn Technologies, Inc.

(21) Appl. No.: 09/957,800

(22) Filed: Sep. 20, 2001

(51) Int. Cl. G01R 27/28

(52) U.S. Cl. 324/615

(57) ABSTRACT

Analysis of a linear time-invariant system's sampled output data can identify the unknown continuous-time transfer function of the system. The method excites the system with two orthogonal sinusoids and constructs a linear complex equation that relates the sampled output points to the unknown values of the transfer function. This method can identify the continuous-time dynamics of a hard disk drive system in which the number of servo bursts and the spinning speed of the disk fix the sampling frequency of the output. In the hard disk case the input excitation signal is passed through a specially designed pre-filter and the sampled output data are modified to account for the control input and external disturbances. The method can also be used to reconstruct the output of the system even in the presence of aliasing provided the input excitation can be approximated by a sum of sinusoids with known frequencies.

### BACKGROUND OF THE INVENTION

1. Field of the Invention

The present invention relates to the identification of a transfer function corresponding to a continuous-time linear time invariant system using the sampled output measurements from that system. The sampled output measurements could be generated at a fixed sampling frequency and the transfer function could be determined despite the presence of aliasing. Implementations of this strategy have application to hard disk drive systems and other similar systems.

2. Description of Related Art

The natural world operates in an analog domain, but information signals are often processed, measured or otherwise manipulated more efficiently in the digital domain. Conversion from the analog domain to the digital domain is accomplished with analog-to-digital converter (ADCs) or conversion may be a natural consequence of the sensing process. An ADC receives as input an analog or continuous-time signal and produces as output a digital signal. The digital signal is a sequence of numbers whose values are equal to the value of the analog signal at the sampling times. For example if y(t) is the analog signal, y(nT), n=0, 1, 2, . . . will be the digital signal and y(nT)=y(t) |_{t=nT} where T is the sampling period of the ADC. Some of the information present in the analog signal is lost during the conversion process. The amount of the information lost depends on how fast the sampling process takes place, i.e., how close to each other the sampling points nT are on the time axis. This implies that the smaller the sampling period T or equivalently the higher the sampling frequency ωₛ=2π/T, the smaller the amount of information lost during the conversion.

In some applications, such as in hard disk drives, analog-to-digital conversion occurs naturally. For a hard disk drive, the position of the head relative to the center of the track is generated in digital form. The head position is generated with a sampling frequency that depends on the spinning speed of the disk and on the number of prewritten sectors on the disk that provide head position information. In the case of the disk drive and other applications, it is sometimes useful to identify the continuous time transfer function of the system to be used for modeling and control design purposes. It is sometimes also useful to reconstruct or estimate the continuous-time output from the sampled output data in order to understand the behavior of the system at points in time other than the sample points.

According to Shannon's sampling theorem, aliasing makes it impossible to recover the information lost during digital conversion if the sampling frequency is less than half the maximum frequency present in the signal. In practice, aliasing can be minimized or avoided by increasing the sampling frequency well above the marginal sampling frequency dictated by Shannon's sampling theorem. In the case of the disk drive and other similar applications the sampling rate is fixed and so increasing the sampling frequency is impractical for a given disk drive design. This implies that for system identification and signal reconstruction to be possible; the highest frequency in the analog signal should be much less than the sampling frequency. Ideally, according to Shannon's sampling theorem, the limiting frequency is half the sampling frequency. The implication of Shannon's sampling theorem for the hard disk drive example is that the dynamics and resonant modes of the system corresponding to frequencies close to and above half of the sampling frequency cannot be identified with conventional methods. Again, this limitation is due to aliasing.

The conventional method of identifying the transfer function of a system from sampled data is to excite the system with a sinusoidal sweep and record the sampled output data. After exciting the system and recording the sampled data, the conventional method continues using a fast Fourier transform method to calculate the values of the transfer function at different frequency points. This method breaks down at frequencies close to and above half of the sampling frequency. Consequently the value of the transfer function at high frequencies cannot be calculated with this conventional method unless the sampling frequency is increased further. Because the sampling frequency of the data positioning information is fixed for a particular disk drive system, it is not possible to increase the sampling frequency unless additional position data sectors are added and/or the spinning speed is increased further.

In at least some instances it would be useful to provide a method for identifying the transfer function of a continuous time system from sampled output data at frequencies higher than half the sampling frequency.

### SUMMARY OF THE INVENTION

An aspect of the present invention provides a method of identifying a transfer function for a system. The method provides the system with a first and second sinusoidal driving signal, the first driving signal out of phase with the second driving signal. The system is excited with the first driving signal over a range of frequencies and the method samples a measurable system output responsive to the first driving signal to generate a first set of sampled output data. The system is excited with the second driving signal over the range of frequencies and the method samples a measurable system output responsive to the second driving signal to generate a second set of sampled output data. The method determines at least one value of a transfer function from the first and second sets of sampled output data.

Another aspect of the present invention provides a method of identifying a transfer function for a system. The method provides the system with a first and second sinusoidal driving signal, the first driving signal out of phase with the second driving signal. The system is excited with the first driving signal over a range of frequencies and the method samples a measurable system output responsive to the first driving signal to generate a first set of sampled output data. The system is excited with the second driving signal over a range of frequencies and the method samples a measurable system output responsive to the second driving signal to generate a second set of sampled output data. The method determines at least one value of a transfer function from the first and second sets of sampled output data. The method determines a second value of the transfer function at a frequency different from the first value of the transfer function from the first and second signal sets obtained by exciting the system with the first and second signals.

Still another aspect of the present invention provides a method of identifying a transfer function for a system. The method provides the system with a first and second sinusoidal driving signal, the first driving signal out of phase with the second driving signal. The system has a filter having a filter response function such that a product of the transfer function and the filter response function has bounded values. Both the first and the second driving signals are passed through the filter before being applied to the system. The system is excited with the filtered first driving signal over a range of frequencies and the method samples a measurable system output responsive to the filtered first driving signal to generate a first set of sampled output data. The system is excited with the filtered second driving signal over a range of frequencies and the method samples a measurable system output responsive to the filtered second driving signal to generate a second set of sampled output data. The method determines at least one value of a transfer function from the first and second sets of sampled output data. The method determines a second value of the transfer function at a frequency different from the first value of the transfer function from the first and second signal sets obtained by exciting the system with the first and second signals.

### BRIEF DESCRIPTION OF THE DRAWINGS

FIG. 1 illustrates a block diagram of a system model in which the input and output signals are measurable and aspects of the present invention are used to determine the transfer function of the system. The FIG. 1 system has stable poles.

FIG. 2 illustrates a block diagram of a system model in which the input and output signals are measurable and aspects of the present invention are used to determine the transfer function of the system. The FIG. 2 system has unstable poles.

FIG. 3 illustrates a block diagram of a system model in which the input and output signals are measurable and aspects of the present invention are used to determine the transfer function of the system. The FIG. 3 system is in a closed loop configuration.

FIG. 4 illustrates a block diagram of a model hard disk drive system in a closed loop configuration, in which the input and output signals are measurable and aspects of the present invention are used to determine the transfer function of the system.

FIG. 5 illustrates a block diagram of a more complete model of a hard disk drive system in a closed loop configuration, in which the input and output signals are measurable and aspects of the present invention are used to determine the transfer function of the system.

FIG. 6 illustrates a block diagram of a system model in which the input and output signals are measurable and aspects of the present invention are used to reconstruct the signal.

FIG. 7 shows the Bode diagram for a first example determining the transfer function of a system having stable poles.

FIG. 8 illustrates a block diagram of a system model in which the input and output signals are measurable and aspects of the present invention are used to determine the transfer function of the system. The FIG. 8 system is in an open loop configuration.

FIG. 9 shows the Bode diagram for the FIG. 8 open loop system and an exemplary simulation of determining the transfer function of the system.

FIG. 10 shows the Bode diagram for the FIG. 8 system operated in a closed loop configuration and an exemplary simulation of determining the transfer function of the system.

FIG. 11 illustrates a square wave input to a system and an estimation of that square wave input.

FIG. 12 shows the simulation results of inputting the estimated square wave into the system of FIG. 1 and reconstructing the system output.

### DETAILED DESCRIPTION OF THE PREFERRED EMBODIMENTS

Analysis of a linear time-invariant system's sampled output data can be used to identify the continuous-time transfer function of the system. The method can identify the unknown transfer function of a system at frequencies that violate Shannon's sampling theorem. The method preferably is based on exciting the system with two orthogonal sinusoids and constructing a linear complex equation that relates the sampled output points to the unknown values of the transfer function. Appropriate equations are illustrated here that are independent of aliasing and always have a solution. An illustrative and advantageous application of the method is in identifying the continuous-time dynamics of a hard disk drive system where the number of servo bursts and the spinning speed of the disk fix the sampling frequency of the sampled output data. When applying this method to the hard disk drive system, particularly preferred implementations pass the input excitation signal through a specially designed pre-filter and the output sampled data preferably are modified to account for the control input and external disturbances. The method can also be used to reconstruct the output of a system from the sampled output data despite aliasing provided the input excitation can be approximated by a sum of sinusoids with known frequencies.

Preferred implementations of this strategy are discussed in terms of sinusoidal functions. Those of ordinary skill appreciate that sinusoidal functions include cosine functions and sums of sinusoidal functions. Sinusoidal functions are particularly preferred and advantageous due to the simplicity that they present for the method and especially in the computational aspects of the method. Most preferably, two orthogonal sinusoidal functions are used to excite the system under analysis at least in frequency regions where aliasing might occur. An example of orthogonal sinusoids is a sine and cosine pair. In this case, orthogonal means ninety degrees out of phase. It is possible for different types of orthogonality to be used, but the computations are expected to be much more complicated and time consuming.

There are many instances in which it is advantageous to identify the transfer function of a continuous time system using the digitized output of the system. Identifying the transfer function characterizes the system in a way that is very useful for control design purposes and/or modeling. The need for such characterization appears in almost every practical control system problem. In the case of a hard disk drive system, where the sampling frequency of the output is fixed by the design of the disk drive, characterizing the high frequency dynamics and resonant frequencies helps design or tune the servo controller parameters to improve the performance of the servo controller. Improved servo controller performance in turn can lead to a more precise tracking of the disk drive head with respect to the center of the data tracks. Improved servo controller performance facilitates disk drives that are smaller than conventional drives for the same capacity of data.

In an exemplary and presently preferred implementation, the strategy calculates a system transfer function at a wide range of specified frequencies by exciting the system sequentially with two orthogonal sinusoidal signals. The frequencies of the two sinusoidal signals are varied over the range of interest. Preferred implementations of the strategy use the corresponding measured or sampled output data to construct an algebraic complex equation that relates the unknown values of the transfer function at the frequencies of interest with the sampled output data. This equation is independent of aliasing and always has a solution. The estimate of the transfer function at the frequency point of interest is the average of all the output samples weighted by the values of the input excitation signal. This process is repeated for each frequency, the data are used to construct a Bode diagram for the system and standard curve fitting techniques are applied to the Bode diagram to obtain the transfer function. The use of two orthogonal sinusoids may be reduced to the use of a single sinusoid if the excitation frequency is not close to half or to an integer multiple of the sampling frequency and the noise level is low. This case requires calculating the inverse of a large matrix. When the transfer function has unstable poles, the method preferably passes the excitation signal through a specially designed pre-filter before applying the excitation signal to the system. When the unstable system is operating under closed loop control, in addition to the pre-filter, the output of the controller preferably is passed through a specially designed filter whose output is used to modify the measured digitized output of the system before the measured digitized output is used for identification.

An advantage of the strategies described here is that it enables Bode diagram construction at all frequencies of interest without having to increase the sampling frequency. This in turn allows the identification of the transfer function of the continuous time system over a wide frequency range where conventional methods break down.

Another technical advantage of the described strategy is that it can be used, among other applications, to occasionally check the validity of the control system model of a control feedback system in which the sampling frequency is limited. Typical control system models are generated from the Bode diagram of the system on which the control design is based and are used to adjust the controller parameters and improve performance. A particularly advantageous application of the described methods and apparatus are to identify the high resonant frequencies of a hard disk drive system. Hard disk drive systems characteristically measure the position error signal at a fixed sampling rate determined by the number of position sectors on the disk and the spinning speed of the disk. As discussed above, such systems conventionally are unable to be appropriately characterized with limited sampling frequencies due to aliasing. Thus, changes in the resonant frequencies of the system cannot reliably be determined. Knowledge of the resonant frequencies allows the tuning of the servo controller to improve the tracking performance of the hard disk servo controller in addition to other benefits.

The described methods can be used to reconstruct the output of an unknown linear system for a wide class of input signals despite the presence of aliasing in the digitized system output.

Aspects of the strategies described here can be used to calculate the transfer function of the continuous time system from the measured digitized output despite the presence of aliasing and in violation of Shannon's sampling theorem. Shannon's sampling theorem states that a signal cannot be reconstructed from its sampled values unless the sampling frequency is greater than twice the maximum frequency in the signal. In some applications the sampling frequency at which a signal is sampled and observed is fixed by hardware considerations or by the nature of the problem. Hard disk drives are such a system. The position error signal representative of misalignment between the head and the data track center line is generated at a frequency dictated by the number of sectors on the disk that provide position error information and the spinning speed of the disk. This specific problem is discussed here as an example of the analysis and considerations that appear in many applications.

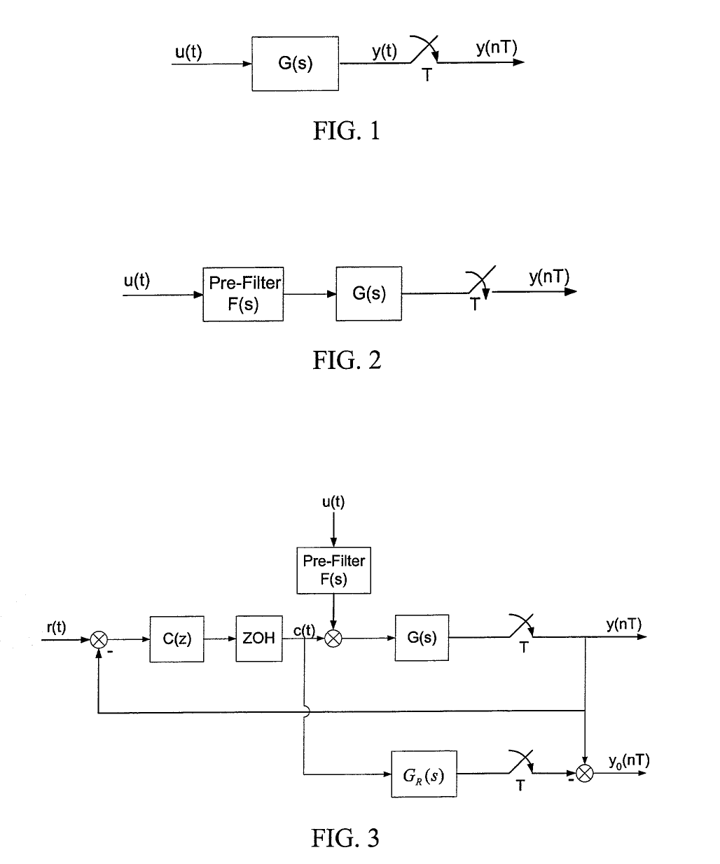

FIG. 1 shows a system block diagram illustrative of aspects of this discussion. In FIG. 1, G(s) is an unknown transfer function of a system, u(t) is the signal input to the system, and y(nT) is the output sampled every T seconds. In this illustration, the output y(t) is not available for measurement but y(nT) and u(t) are measurable. According to Shannon's sampling theorem the output y(t) cannot be reconstructed from y(nT) even in the ideal case unless the sampling frequency ωₛ=2π/T is greater than twice the maximum frequency in y(t).

In practice, computational errors do not prevent y(t) from being reconstructed if its maximum frequency is well below ωₛ/2. For frequencies close to and above ωₛ/2 aliasing takes place. When systems are characterized by aliasing, ideal filtering or any kind of signal reconstruction conventionally cannot reliably determine y(t) from y(T). This problem prevents the generation of a Bode diagram for G(s) using conventional methods for frequencies close to and above ωₛ/2. This is problematic because, as discussed above, the Bode diagram is used in estimating G(s) for control design and modeling purposes.

A particularly preferred aspect of the discussed strategy bypasses the limitations of Shannon's sampling theorem by designing the input excitation signal u(t) so that calculating G(jωᵢ) at any finite frequency ωᵢ from the sampled output data y(nT) is computationally feasible even in the presence of aliasing.

Identification of the Continuous-Time Transfer Function of Stable Systems

The identification of G(s) in FIG. 1 involves exciting the system over a certain frequency range, constructing a Bode diagram that represents the frequency response of the system and calculating G(s) from the Bode diagram by using standard curve fitting techniques. Once determined for a given system, G(s) is used for modeling and for design of the control system. The conventional method for generating a Bode diagram is to excite the system with a rich frequency signal and record the output sequences. Then the conventional method computes the discrete time Fourier transform (DTFT) or fast Fourier transform (FFT) for both the input and output sequences. The value of the transfer function at a particular frequency is computed from the knowledge of the spectra of the output and input signal at that frequency. In FIG. 1, however, only y(nT) is available for measurement and at frequencies ωᵢ≧ωₛ/2 the sequence y(nT) does not imply a unique y(t) due to aliasing. In fact an infinite number of y(t) signals are equal to y(nT) at t=nT. In the frequency domain, this means that at high frequencies that violate Shannon's sampling theorem, folding takes place so that the digitized output spectrum consists of overlapping spectra of the continuous-time output that are shifted by multiples of the sampling frequency. The continuous-time output spectrum cannot be calculated from the digitized output spectrum due to this aliasing. Consequently the current FFT methods used for identification of transfer functions and characterization of systems break down in this frequency region.

The preferred strategies described here for estimating G(jωᵢ) at any given frequency provide a time domain approach and take particular advantage of a preferred way of exciting the system to be characterized. In particularly preferred implementations, the system is excited by:

u(t)=sin ωᵢt

and

u(t)=cos ωᵢt

over non-overlapping intervals of time. Let

Yₛ=[yₛ(T) yₛ(2T) . . . yₛ(KT)]^{T}

be the vector with the values of y(nT) when u(t)=sin ωᵢt is used and

Y_{c}=[y_{c}(T) y_{c}(2T) . . . y_{c}(KT)]^{T}

is the vector with the values of y(nT) when u(t)=cos ωᵢt is used. Let

Y=Y_{c}jYₛ

and

$$H = [ \begin{matrix}{ⅇ}^{{jω}_{i} T} \\ {ⅇ}^{{jω}_{i} 2 T} \\ ⋮ \\ {ⅇ}^{{jω}_{i} K T}\end{matrix} ] .$$

Then Ĝ(jωᵢ) is calculated from

Ĝ(jωᵢ)=H⁺Y/K

where H⁺ is the complex conjugate of H. The above equation is independent of aliasing and has always a solution. The number of data collected in Y depends on the accuracy required. Since only Y depends on the real data, the presence of noise gets averaged and the estimation of Ĝ(jωᵢ) is unbiased. The process of excitation is repeated for different to values of ωᵢ and a Bode diagram is constructed using the pairs Ĝ(jωᵢ), ωᵢ. The transfer function G(s) is then calculated from the Bode diagram using standard techniques.

The process of exciting the system using two orthogonal sinusoids can be simplified for frequencies of interest whose value is away from a half or an integer multiple of the sampling frequency. In this case the system in FIG. 1 is excited by the input

u(t)=sin ωᵢt,

where ωᵢ is kept constant over the time internal [0, KT], where K≧2 is the number of data to be obtained in the sample y(nT) that reflect the effect of exciting the system with sin ωᵢt. Then ωᵢ is changed to the next value of interest over the interval [KT, 2KT]. The process continues for all ωᵢ that are not close to mωₛ with m=±½, ±1, ±2, . . . .

For each frequency ωᵢ, form

Y=2j[y(1)y(2) . . . y(KT)]^{T}

and

$$H = [ \begin{matrix}{ⅇ}^{{jω}_{i} T} & {ⅇ}^{- {jω}_{i} T} \\ {ⅇ}^{{jω}_{i} 2 T} & {ⅇ}^{- {jω}_{i} 2 T} \\ ⋮ & ⋮ \\ {ⅇ}^{{jω}_{i} K T} & {ⅇ}^{- {jω}_{i} K T}\end{matrix} ] .$$

Then Ĝ(jωᵢ) is calculated using the equation

[Ĝ(jωᵢ)−Ĝ(−jωᵢ)]^{T}=(H⁺H)⁻¹H⁺Y

From Ĝ(jωᵢ) the method obtains |Ĝ(jωᵢ)| and ∠Ĝ(jωᵢ) that together define one point on the Bode diagram at the frequency ωᵢ. By repeating the above calculations for each ωᵢ more points are obtained and the Bode diagram is constructed. From the Bode diagram, G(s) can be calculated using standard curve fitting techniques.

The above described method conventionally fails in the presence of a high level of aliasing. For example, when ωᵢ=mωₛ, where m=±½, ±1, ±2, . . . , the inverse of H⁺H does not exist. In practice the inverse of H⁺H may not be computable when co, is close to mωₛ or, if it is computable, the computed inverse may provide inaccurate estimates of G(jωᵢ) due to noise effects and other inaccuracies. For this reason, when ωᵢ≧ωₘₐₓ, where ωₘₐₓ is the maximum frequency of excitation that does not cause aliasing, the first method using two orthogonal sinusoids for exciting the system is more appropriate. The general strategy here can use excitation signals whose phase difference is less than 90 degrees. Orthogonality between the excitation signals (i.e., a phase difference of 90 degrees), however, is particularly preferred because it simplifies calculations considerably as the inverse of a large matrix need not be computed.

The above described method relies on the assumption that the system transfer function has stable poles. Because the transfer function of this case has stable poles, driving the system with a bounded input produces a bounded output from the system. The described strategy however can also be used to handle cases where the transfer function has unstable poles. The case of unstable poles is discussed next.

Identification of the Continuous-Time Transfer Function of Unstable Systems

Identifying the transfer function of a continuous-time system using input excitation at different frequencies relies on the assumption that the system is stable so that a bounded input signal to the system will result in a bounded output signal from the system. If the system is unstable then excitation signals of the form

u(t)=sin(ωᵢt)u₋₁(t)

and

u(t)=cos(ωᵢt)u₋₁(t)

over non-overlapping intervals of time, where u₋₁(t) is a unit step function, will lead to an unbounded output. To address this problem, certain preferred implementations of this aspect of the strategy pass the excitation signals through an appropriately designed pre-filter before applying the listed functions as excitation signals. Such a system including the pre-filter to the system is shown in FIG. 2.

The pre-filter F(s) most preferably is designed such that F(s)G(s) has a bounded impulse response. In other words, F(s) is designed to have zeros at the positions that the system G(s) has unstable poles, which positions are assumed to have been determined. In practice the unstable poles of G(s) may not be cancelled exactly by the zeros of F(s), leading to a function F(s)G(s) that has unstable poles. The presence of F(s) however, reduces the effect of the instability in which case the magnitude of the output signal does not grow unbounded as fast, generally providing sufficient time to collect output data.

The system is driven by the two excitation signals listed immediately above. The output data collected are used to form a vector

Yₛ=[yₛ(T)yₛ(2T) . . . yₛ(KT)]^{T}

with the values of y(nT) when u(t)=sin ωᵢt is used to excite the system and

Y_{c}=[y_{c}(T)y_{c}(2T) . . . y_{c}(KT)]^{T}

with the values of y(nT) when u(t)=cos ωᵢt is used to excite the system. Let

Y=Y_{c}+jYₛ

and

$$H = [ \begin{matrix}{ⅇ}^{{jω}_{i} T} \\ {ⅇ}^{{jω}_{i} 2 T} \\ ⋮ \\ {ⅇ}^{{jω}_{i} K T}\end{matrix} ] .$$

Then ĜF(jωᵢ) is calculated from

ĜF(jωᵢ)=H⁺Y/K

The magnitude and phase of Ĝ(jωᵢ) are obtained as:

20log{|Ĝ(jωᵢ)|}=20log{|ĜF(jωᵢ)|}−20log{|F(jωᵢ)|} and

∠Ĝ(jωᵢ)=∠ĜF(jωᵢ)−∠F(jωᵢ).

On the other hand, for frequencies of interest whose values are away from a half or an integer multiple of the sampling frequency, the excitation signal can be simplified by using a single sinusoid u(t)=sin(ωᵢt)u₋₁(t). In this case, the output data collected are used to form the vector

Y=2j[y(1)y(2) . . . y(KT)]^{T}

and,

$$H = [ \begin{matrix}{ⅇ}^{{jω}_{i} T} & {ⅇ}^{- {jω}_{i} T} \\ {ⅇ}^{{jω}_{i} 2 T} & {ⅇ}^{- {jω}_{i} 2 T} \\ ⋮ & ⋮ \\ {ⅇ}^{{jω}_{i} K T} & {ⅇ}^{- {jω}_{i} K T}\end{matrix} ] .$$

Let ĜF(jωᵢ) denote the estimate of G(jωᵢ)F(jωᵢ). ĜF(jωᵢ) is calculated using the following equation:

[ĜF(jωᵢ)−ĜF(jωᵢ)]^{T}=(H⁺H)⁻¹H⁺Y

Then the magnitude and phase of Ĝ(jωᵢ) are obtained as:

20log{|Ĝ(jωᵢ)|}=20log{|ĜF(ωᵢ)|}−20log{|F(jωᵢ)|} and

∠Ĝ(jωᵢ)=∠ĜF(jωᵢ)−∠F(jωᵢ).

These procedures are repeated over the appropriate (valid) range of frequencies of interest and combined with the other measurements so that a Bode diagram is constructed that can be then used to identify G(s) by following standard curve fitting or other techniques.

Identification of the Continuous-Time Transfer Function of Unstable Systems in a Closed-Loop Configuration

The general methods and systems described here can also be used to identify the unknown transfer function of an uncharacterized open loop system when that system is in a close loop configuration. FIG. 3 shows such a system with a transfer function G(s) controlled by a discrete time controller with transfer function C(z). r(t) is a reference input. The controller is designed a priori based on some approximate knowledge of G(s) to achieve close loop stability. Let G_{R}(s) be an approximation of G(s) on which the design of C(z) is based on and it is therefore known.

The present methods and systems identify G(s) in the configuration shown in FIG. 3 in the following manner. An input u(t) is passed through a pre-filter F(s) designed so that F(s)G(s) has stable poles and is input to the system characterized by G(s). The locations of the unstable poles of G(s) are determined a priori. The output y₀(nT) is constructed as shown in FIG. 3 by subtracting from the measured output signal y(nT) the effect of c(t) generated by the controller, i.e., G_{R}(s)c(t).

The system most preferably is excited by

u(t)=sin ωᵢt

and

u(t)=cos ωᵢt

over non-overlapping intervals of time.

Let

Y₀ₛ=[y₀ₛ(T)y₀ₛ(2T) . . . y₀ₛ(KT)]^{T}

be the vector with the values of y₀(nT) when u(t)=sin ωᵢt is used to excite the system and

Y_{0c}=[y_{0c}(T)y_{0c}(2T) . . . y_{0c}(KT)]^{T}

be the vector with the values of y₀(nT) when u(t)=cos ωᵢt is used to excite the system.

Let

Y=Y_{0c}+jY₀ₛ

and

$$H = [ \begin{matrix}{ⅇ}^{{jω}_{i} T} \\ {ⅇ}^{{jω}_{i} 2 T} \\ ⋮ \\ {ⅇ}^{{jω}_{i} K T}\end{matrix} ] .$$

Then ĜF(jωᵢ) is calculated from

ĜF(ωᵢ)=H⁺Y/K

Then the magnitude and phase of G(jo,) are obtained as:

20log{|Ĝ(jωᵢ)|}=20log{|ĜF(jωᵢ)|}−20log{|F(jωᵢ)|} and

∠Ĝ(jωᵢ)=∠ĜF(jωᵢ)−∠F(jωᵢ).

Preferably these tests are repeated for each frequency of interest so that a Bode diagram is constructed that can be then used to identify G(s) by following standard curve fitting or other techniques.

For frequencies whose values ωᵢ≠mωₛ, m=±½, ±1, ±2, . . . the process can be simplified by using only one sinusoid signal u(t)=sin ωᵢt. The output data collected are used to form the vector

Y=2j[y(1)y(2) . . . y(KT)]^{T}

and,

$$H = [ \begin{matrix}{ⅇ}^{{jω}_{i} T} & {ⅇ}^{- {jω}_{i} T} \\ {ⅇ}^{{jω}_{i} 2 T} & {ⅇ}^{- {jω}_{i} 2 T} \\ ⋮ & ⋮ \\ {ⅇ}^{{jω}_{i} K T} & {ⅇ}^{- {jω}_{i} K T}\end{matrix} ] .$$

Let ĜF(jωᵢ) denote the estimate of Ĝ(jωᵢ)F(jωᵢ). ĜF(jωᵢ) is calculated using the following equation.

[ĜF(jωᵢ)−ĜF(jωᵢ)]^{T}=(H⁺H)⁻¹H⁺Y.

Then the magnitude and phase of Ĝ(jωᵢ) are obtained as:

20log{|Ĝ(jωᵢ)|}=20log{|ĜF(jωᵢ)|}−20log{|F(jωᵢ)|} and

Here again, these tests are repeated over the appropriate (valid) range of frequencies of Minterest and combined with the other measurements so that a Bode diagram is constructed that can be then used to identify G(s) by following standard curve fitting or other techniques.

Application to a Hard Disk Drive System

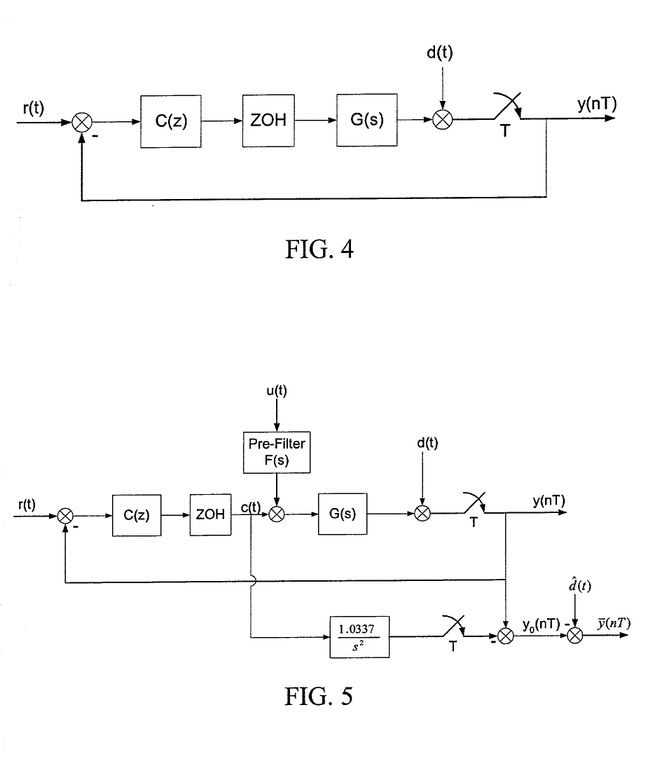

FIG. 4 shows a closed loop configuration of a hard disk drive servo system. In FIG. 4, G(s) represents the dynamics of the disk drive system, C(z) the controller transfer function in the z-domain, d(t) represents the output disturbances due to noise, higher order harmonics, etc. The output y(nT) represents the position error signal (PES), which is the deviation of the position of the head from the center of the track the head is trying to track. Since the position error data are stored only in designated sectors on the surface of the hard disk, referred to as servo bursts, the value of the sampling period T depends on the number of the servo bursts and the spinning speed of the disk. In practical systems, the value of the sampling period T cannot be reduced below a certain value. This implies that the sampling frequency cannot increase beyond a certain value. This in turn implies that the resonant modes of the disk drive system that are close to or above half of the sampling frequency cannot be identified using the conventional methods.

Conventional approaches to bypass this problem include increasing the sampling rate by adding more servo bursts and/or increasing the spinning speed. Both of these approaches have their limitations and are costly. It would be advantageous to have a method of identifying the resonant modes of the system, periodically, and use that knowledge to update the controller parameters for better tracking. Since a small percentage change in the resonant frequencies may affect the performance of the controller appreciably, the occasional monitoring of the location of the resonant frequencies and tuning of the controller parameters can lead to significantly better tracking control performance.

The present invention is applied to the hard disk drive system as shown in FIG. 5 and explained below. For clarity, this discussion considers a particular model of a disk drive system with transfer function G(s) given by:

G(s)=G_{R}(s)\overline{G}(s)

where \overline{G}(s) represents the high resonant frequencies and G_{R}(s) the low frequency dynamics. In disk drives \overline{G}(s) has stable poles, but G_{R}(s) may have unstable poles. In this case the controller C(z) is designed based on the low frequency approximation of G(s), namely G_{R}(s).

A block diagram illustrating the characterization strategy of this method is provided by FIG. 5. For the purpose of illustration we assume that

$${G}_{R} ( s ) = \frac{1.0337}{{s}^{2}} .$$

The pre-filter F(s) is chosen as

$$F ( s ) = \frac{{s}^{2}}{{( s + 10 )}^{2}}$$

such that F(s)G(s) has stable poles. As above, the pre-filter function is selected according to the characteristics of the system and different pre-filter functions may be appropriate to different systems. A characteristic disturbance d(t) of the system has the form

d(t)=D₁ sin(ω_{d}t+φ₁)+D₂ sin(2ω_{d}t+φ₂)+D₃ sin(3ω_{d}t +φ₃)+n_{w},

where ω_{d}=754 (rad/s) is the angular speed of the disk, n_{w} is noise and Dᵢ and φᵢ (i=1, 2, 3) are unknown constants.

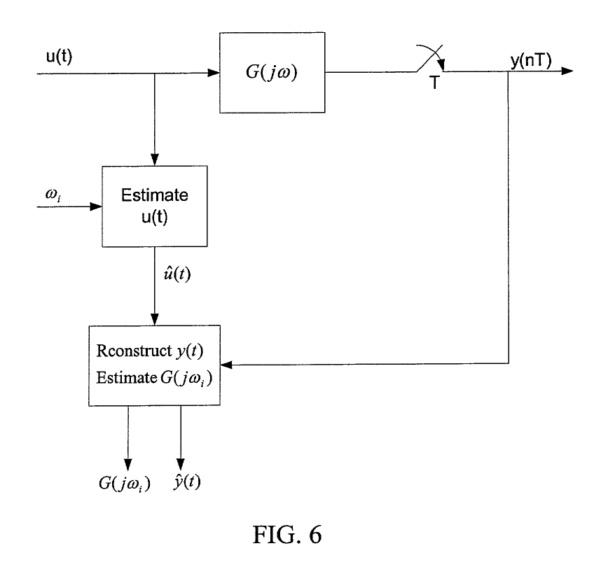

The strategies described above can be applied to derive the open loop transfer function of this hard disk drive system in the following manner. This implementation of the strategy estimates the disturbance d(t) using standard techniques, at the sampling instances, and subtracted from the estimated output y₀(nT) of the disk drive system. Let \hat{d}(t) be the estimate of d(t) at t=nT generated by some standard method and used as shown in FIG. 6. In a particularly preferred implementation, the excitation signal u(t) is chosen as

u(t)=sin ωᵢt

and

u(t)=cos ωᵢt

over non-overlapping intervals of time as described above. As is also described above, the excitation signals need not be orthogonal, but the use of such orthogonal functions is particularly useful for simplifying calculations.

Let

\overline{Y}ₛ=[\overline{y}ₛ(T)\overline{y}ₛ(2T) . . . \overline{y}ₛ(KT)]^{T}

be the vector with the values of y(nT) when u(t)=sin ωᵢt is used to excite the system and

\overline{Y}_{c}=[\overline{y}_{c}(T)\overline{y}_{c}(2T) . . . \overline{y}_{c}(KT)]^{T}

be the vector with the values of \overline{y}(nT) when u(t)=cos ωᵢt is used to excite the system.

Let

Y=\overline{Y}_{c}+j\overline{Y}ₛ

and

$$H = [ \begin{matrix}{ⅇ}^{{jω}_{i} T} \\ {ⅇ}^{{jω}_{i} 2 T} \\ ⋮ \\ {ⅇ}^{{jω}_{i} K T}\end{matrix} ] .$$

Then ĜF(jωᵢ) is calculated from

ĜF(jωᵢ)=H⁺Y/K

Then the magnitude and phase of Ĝ(jωᵢ) are obtained as:

20log{|Ĝ(jωᵢ)|}=20log{|ĜF(jωᵢ)|}|20log{|F(jωᵢ)|} and

∠Ĝ(jωᵢ)=∠ĜF(jωᵢ)−∠F(jωᵢ).

Preferably this process is repeated for each frequency of interest so that a Bode diagram is constructed that can be then used to identify G(s) by following standard curve fitting or other techniques.

As a particularly advantageous aspect of this invention, this framework can also be used to simultaneously estimate d(t) and G(jωᵢ). Let the estimate of \hat{d}(t) be

$$\hat{d} ( t ) = {\sum }_{k = 1}^{3} {\hat{D}}_{ks} sin ( k {ω}_{d} t ) + {\hat{D}}_{kc} cos ( k {ω}_{d} t )$$

where \hat{D}ₖₛ, \hat{D}_{kc}, k=1, 2, 3, are estimated so that \hat{d}(t) is very close to d(t) (within the noise level). Select the input excitation as

u(t)=sin ωᵢt

and

u(t)=cos ωᵢt

over non-overlapping intervals of time. Again, this is a preferred illustration and different, presently less preferred, implementations might not use orthogonal functions.

Let

Y₀ₛ=[y₀ₛ(T)y₀ₛ(2T) . . . y₀ₛ(KT)]^{T}

be the vector with the values of y₀(nT) when u(t)=sin ωᵢt is used to excite the system and

Y_{0c}=[y_{0c}(T)y_{0c}(2T) . . . y_{0c}(KT)]^{T}

be the vector with the values of y₀(nT) when u(t)=cos ωᵢt is used. Let

Y=Y_{0c}+jY₀ₛ

and

$$H = [ \begin{matrix}{ⅇ}^{j {ω}_{i} T} & sin ( {ω}_{d} T ) & cos ( {ω}_{d} T ) & sin ( 2 {ω}_{d} T ) & cos ( 2 {ω}_{d} T ) & sin ( 3 {ω}_{d} T ) & cos ( 3 {ω}_{d} T ) \\ {ⅇ}^{j {ω}_{i} 2 T} & sin ( {ω}_{d} 2 T ) & cos ( {ω}_{d} 2 T ) & sin ( 2 {ω}_{d} 2 T ) & cos ( 2 {ω}_{d} 2 T ) & sin ( 3 {ω}_{d} 2 T ) & cos ( 3 {ω}_{d} 2 T ) \\ ⋮ & ⋮ & ⋮ & ⋮ & ⋮ & ⋮ & ⋮ \\ {ⅇ}^{j {ω}_{i} K T} & sin ( {ω}_{d} K T ) & cos ( {ω}_{d} K T ) & sin ( 2 {ω}_{d} K T ) & cos ( 2 {ω}_{d} K T ) & sin ( 3 {ω}_{d} K T ) & cos ( 3 {ω}_{d} K T )\end{matrix} ]$$

ĜF(jωᵢ) denotes the estimate of G(jωᵢ)F(jωᵢ) and is estimated using the equation

[ĜF(jωᵢ)\hat{D}₁ₛ\hat{D}_{1c}\hat{D}₂ₛ\hat{D}_{2c}\hat{D}^{3s}\hat{D}_{3c}]^{T}=(H⁺H)⁻¹H⁺Y.

Then the magnitude and phase of Ĝ(jωᵢ) are obtained as:

20log{|Ĝ(jωᵢ)|}=20log{|ĜF(jωᵢ)|}−20log{|F(jωᵢ)|} and

∠Ĝ(jωᵢ)=∠ĜF(jωᵢ)−∠F(jωᵢ)

Preferably this process is repeated for each frequency of interest so that a Bode diagram is constructed that can be then used to identify G(s) by following standard curve fitting or other techniques.

For frequencies whose values ωᵢ≠mωₛ, m=±½, ±1, ±2, . . . . the process can be simplified by using only one sinusoid signal, for example, u(t)=sin ωᵢt . In this case we have

$$H = [ \begin{matrix}{ⅇ}^{j {ω}_{i} T} & {ⅇ}^{- j {ω}_{i} T} & sin ( {ω}_{d} T ) & cos ( {ω}_{d} T ) & sin ( 2 {ω}_{d} T ) & cos ( 2 {ω}_{d} T ) & sin ( 3 {ω}_{d} T ) & cos ( 3 {ω}_{d} T ) \\ {ⅇ}^{j {ω}_{i} 2 T} & {ⅇ}^{- j {ω}_{i} 2 T} & sin ( {ω}_{d} 2 T ) & cos ( {ω}_{d} 2 T ) & sin ( 2 {ω}_{d} 2 T ) & cos ( 2 {ω}_{d} 2 T ) & sin ( 3 {ω}_{d} 2 T ) & cos ( 3 {ω}_{d} 2 T ) \\ ⋮ & ⋮ & ⋮ & ⋮ & ⋮ & ⋮ & ⋮ & ⋮ \\ {ⅇ}^{j {ω}_{i} K T} & {ⅇ}^{- j {ω}_{i} K T} & sin ( {ω}_{d} K T ) & cos ( {ω}_{d} K T ) & sin ( 2 {ω}_{d} K T ) & cos ( 2 {ω}_{d} K T ) & sin ( 3 {ω}_{d} K T ) & cos ( 3 {ω}_{d} K T )\end{matrix} ]$$

The magnitude and phase of G(jωᵢ) are obtained as:

20log{|Ĝ(jωᵢ)|}=20log{|ĜF(jωᵢ)|}−20log{|F(jωᵢ)|} and

∠Ĝ(jωᵢ)=∠ĜF(jωᵢ)−∠F(jωᵢ).

Here again, this process is repeated over the appropriate (valid) range of frequencies of interest and combined with the other measurements in the problematic, aliasing range, so that a Bode diagram is constructed that can be then used to identify G(s) by following standard curve fitting or other techniques.

Output Signal Reconstruction

The general methods and systems described here can also reconstruct the continuous output of the system in FIG. 1 using its digitized output for a class of input signals that are of the form or can be approximated as

$$u ( t ) = {\sum }_{i = 1}^{N} \{ {A}_{i} sin ( {ω}_{i} t ) + {B}_{i} cos ( {ω}_{i} t ) \}$$

where ωᵢ=1, 2, . . . , N are known frequencies but Aᵢ, Bᵢ are unknown constants. It is desirable here to reconstruct y(t) and identify G(jωᵢ) from the measurements of y(nT).

An illustration of a block diagram that can be used for reconstruction is shown in FIG. 6. It is assumed that ωᵢ≠mωₛ for any m=±½, ±1, ±2, . . . . The preferred reconstruction method generates an estimate û(t) of u(t) as

$$\hat{u} ( t ) = {\sum }_{i = 1}^{N} \{ {\hat{A}}_{i} sin {ω}_{i} t + {\hat{B}}_{i} cos {ω}_{i} t \} , \text{with}$$

\dot{Â}ᵢ=−γᵢε sin ωᵢt, \dot{\hat{B}}ᵢ=−βᵢε cos ωᵢt, ε=û(t)−u(t)

where γᵢ>0, βᵢ>0 are design constants and i=1, 2, . . . , N. The above equations can be expressed in discrete time form and a non-recursive approach can alternatively be used to estimate û(t). The reconstruction ŷ(t) of y(t) and estimation of G(jωᵢ) preferably is generated in the following manner.

$$\hat{y} ( t ) = {\sum }_{i = 1}^{N} \{ {\hat{A}}_{i} \vert \hat{G} ( j {ω}_{i} ) \vert sin ( {ω}_{i} t + ∠ \hat{G} ( j {ω}_{i} ) ) + {\hat{B}}_{i} \vert \hat{G} ( j {ω}_{i} ) \vert cos ( {ω}_{i} t + ∠ \hat{G} ( j {ω}_{i} ) ) \} . \\ {[ \begin{matrix}\hat{G} ( j {ω}_{1} ) & ⋯ & \hat{G} ( j {ω}_{N} ) & - \hat{G} ( - j {ω}_{1} ) & ⋯ & - \hat{G} ( - j {ω}_{N} )\end{matrix} ]}^{T} = {( {\hat{H}}^{+} \hat{H} )}^{- 1} {\hat{H}}^{+} Y . \\ \hat{H} = [ \begin{matrix}{\hat{C}}_{1} {ⅇ}^{j {\tilde{ω}}_{1} T} & ⋯ & {\hat{C}}_{N} {ⅇ}^{j {\tilde{ω}}_{N} T} & {\hat{C}}_{1}^{*} {ⅇ}^{- j {\tilde{ω}}_{1} T} & ⋯ & {\hat{C}}_{N}^{*} {ⅇ}^{- j {\tilde{ω}}_{N} T} \\ {\hat{C}}_{1} {ⅇ}^{j {\tilde{ω}}_{1} 2 T} & ⋯ & {\hat{C}}_{N} {ⅇ}^{j {\tilde{ω}}_{N} 2 T} & {\hat{C}}_{1}^{*} {ⅇ}^{- j {\tilde{ω}}_{1} 2 T} & ⋯ & {\hat{C}}_{N}^{*} {ⅇ}^{- j {\tilde{ω}}_{N} 2 T} \\ ⋮ & ⋰ & ⋮ & ⋮ & ⋰ & ⋮ \\ {\hat{C}}_{1} {ⅇ}^{j {\tilde{ω}}_{1} K T} & ⋯ & {\hat{C}}_{N} {ⅇ}^{j {\tilde{ω}}_{N} K T} & {\hat{C}}_{1}^{*} {ⅇ}^{- j {\tilde{ω}}_{1} K T} & ⋯ & {\hat{C}}_{N}^{*} {ⅇ}^{- j {\tilde{ω}}_{N} K T}\end{matrix} ] . \\ Y = {2 [ \begin{matrix}y ( T ) & y ( 2 T ) & ⋯ & {y ( K T )}^{2}\end{matrix} ]}^{T} .$$

where Ĉᵢ=\hat{B}ᵢ−jÂⱼ, K≧2N, (.)⁺ denotes conjugate transpose, (.)* denotes conjugation, and \tilde{ω}ᵢ=ωᵢ−mωₛ. In the presence of aliasing, it is possible for m to take values ±1, ±2, . . . . In the absence of aliasing m=0. Since e^{j\tilde{ω}}^{ᵢ}^{T}=e^{jω}^{ᵢ}^{T} irrespective of the value of m, the value of the preferred matrix Ĥ and of ŷ(t) is not affected by aliasing. For (Ĥ⁺Ĥ)⁻¹ to exist, the rank of Ĥ most preferably equals 2N. This condition is ensured provided ωᵢ isnotcloseto mωₛ, m=±½, ±1, ±2, . . . .

### EXAMPLES

Applications and advantages of the preferred implementations described above are demonstrated using simulations, the results of which are presented below.

### Example 1

### Transfer Function Identification

For the purpose of this demonstration, \overline{G}(s) can be selected to be of the form

$$\overline{G} ( s ) = \frac{\overline{N} ( s )}{\overline{D} ( s )} , \text{where}$$

\overline{N}(s)=0.0205s⁸−17545s⁷+7.7716×10⁸s⁶−1.6578×10¹⁴s⁵+9.4397×10¹⁸s⁴−4.5821×10²³s3+3.5921×10²⁸s²−3.7757×10³²s+4.3497×10³⁷ and

\hat{D}(s)=s⁸+4502.0s⁷+1.1553×10⁷s⁶+3.9934×10¹³s⁵+4.6555×10¹⁹s⁴+1.1323×10²³s³+7.6438×10²⁸s²+1.0242×10³²s+4.21×10³⁷.

The output of the system dynamics is the position error signal that is measured at a frequency of 12.72 kHz or 79,922.1 rad/sec. An implementation of the described method is used to estimate Ĝ(jωᵢ) at any frequency of interest ωᵢ.

Most preferably, the input to the system is chosen as

u(t)=sin(ωᵢt)

where ωᵢ is varied from 0 to ωₘₐₓ where ωₘₐₓ<<ωₛ/2 and ωₛ=2π×12.72×10³ rad/sec. In this case aliasing is not present and Gₕ(jωᵢ), ωᵢ∈[0, ωₘₐₓ] can be calculated using conventional methods. For ωᵢ>ωₘₐₓ, where aliasing is a consideration, most preferably two inputs

u(t)=sin(ωᵢt) and u(t)=cos(ωᵢt)

are applied sequentially over selected intervals of time that do not overlap. Preferably the time intervals are selected to be large enough to generate a sufficient number of output samples. For each ωᵢ the described method is used to generate Ĝₕ(jωᵢ) and the magnitude |Gₕ(jωᵢ)| and phase ∠Gₕ(jωᵢ) are calculated. Table 1 shows a comparison of the actual values and estimated ones for frequencies well above the sampling frequency. In this example, the measurements of y(nT) include a Gaussian noise with zero mean and standard deviation of 0.2.

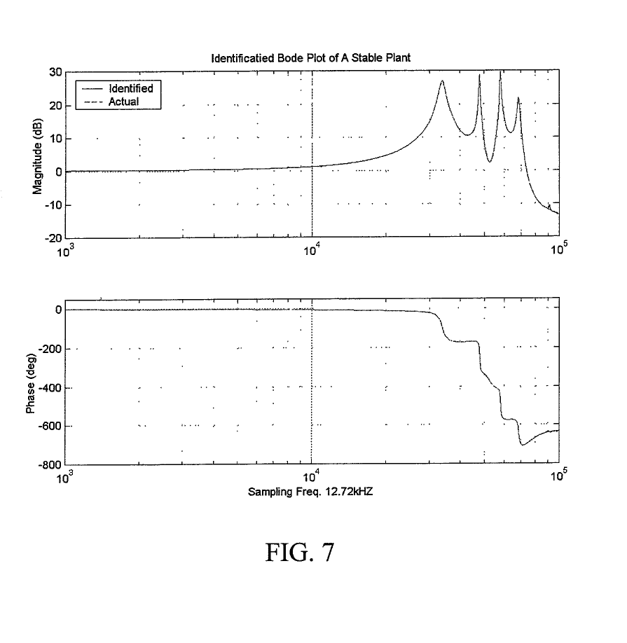

The Bode diagram of the actual system and estimated one is presented in FIG. 7. Table 1 and FIG. 7 illustrate the efficiency of the preferred methods and systems described here.

TABLE 1
Comparing original model with identified mode at different frequency points.
Sampling Frequency ωs = 12.72 kHz or 79,922.1 rad/sec

| Freq. Points ωₗ | Actual Magnitude | Estimated Magnitude | Actual Phase | Estimated Phase |
|---|---|---|---|---|
| (rad/s) | \|Gₕ(jωᵢ)\| in dB | \|Ĝₕ(jωₗ)\| in dB | ∠Gₕ(jωᵢ) in deg | ∠Ĝₕ(jωₗ) in deg |
| 20000 | 4.5495 | 4.5399 | −12.1355 | −12.1717 |
| 30000 | 14.7695 | 14.7507 | −23.3778 | −23.3697 |
| 33853 | 26.8598 | 26.8308 | −98.0598 | −97.6469 |
| 48000 | 28.7098 | 28.6273 | −251.9127 | −250.3148 |
| 58146 | 29.6903 | 29.5944 | −133.8451 | −132.3666 |
| 68666 | 21.9161 | 21.8793 | −284.1586 | −283.3310 |
| 700000 | 13.6851 | 13.7590 | −341.3407 | −341.0366 |
| 10⁵ | −13.2273 | −13.2622 | −272.4926 | −272.5306 |
| 10⁶ | −31.5022 | −26.5927 | −318.3686 | −296.9552 |

### Example 2

### Identification of the Dynamics of a HDD System in an Open-Loop Configuration

For purposes of this exemplary simulation, assume that the dynamics of a hard disk drive (HDD) system are

$$G ( s ) = \frac{1.0337}{{s}^{2}} \overline{G} ( s ) .$$

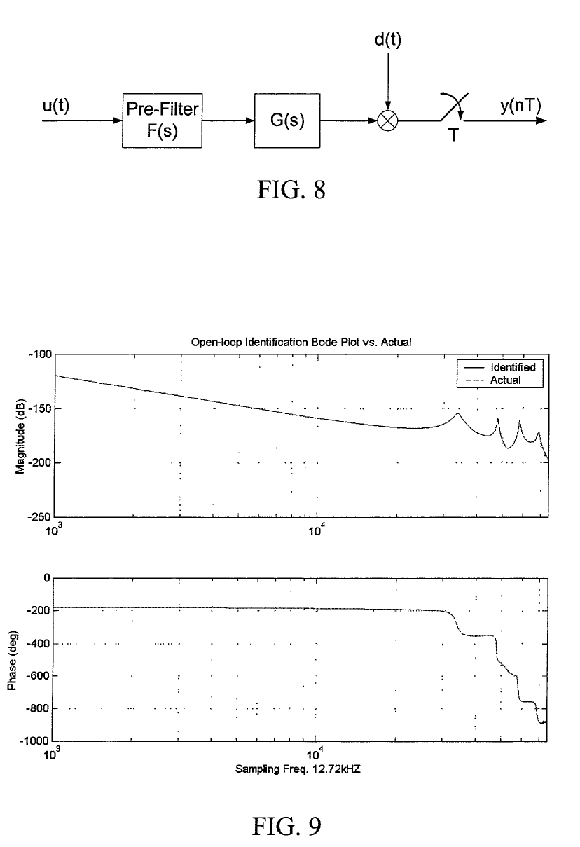

Most preferably, the stable pre-filter F(s)=s²/(s+10)² is constructed such that F(s)G(s) has stable poles. In this case the feedback loop is disconnected as shown in FIG. 8 so that the open loop configuration of the system is characterized. The characterization is accomplished in the manner described above for such a system. The Bode diagram generated for G(s) is presented in FIG. 9 and shown in Table 2.

TABLE 2
Including Gaussian Noise with Zero Mean and Standard Deviation 3 × 10⁻⁸

| Freq. | Actual System | | Open-loop Estimation | | Closed-loop Estimation | |
|---|---|---|---|---|---|---|
| Points | | Phase | | Phase | | Phase |
| (rad/s) | Mag. (dB) | (deg) | Mag. (dB) | (deg) | Mag. (dB) | (deg) |
| 100 | −79.7164 | −180.0637 | −79.7235 | −180.0921 | −79.7117 | −179.9984 |
| 1000 | −119.7076 | −180.6366 | −119.7009 | −180.6605 | −119.7101 | −179.9484 |
| 20000 | −167.4917 | −192.1355 | −167.4697 | −192.0469 | −167.6362 | −196.8404 |
| 30000 | −164.3153 | −203.3778 | −164.3314 | −203.2680 | −164.9278 | −204.1158 |
| 33853 | −154.3241 | −278.0598 | −154.3475 | −277.6308 | −154.9899 | −268.9914 |
| 48000 | −158.5398 | −71.9127 | −158.5904 | −69.1207 | −159.3689 | −64.6243 |
| 58146 | −160.8905 | −313.8451 | −160.9610 | −311.3364 | −162.1194 | −305.1481 |
| 68666 | −171.5536 | −104.1586 | −171.5547 | −102.3250 | −171.2437 | −98.5231 |
| 70000 | −180.1188 | −161.3407 | −179.9732 | −161.0215 | −179.6061 | −151.4613 |
| 10⁵ | −213.2273 | −92.4926 | −210.5540 | −116.5133 | −200.3397 | −164.0347 |

### Example 3

### Identification of the Dynamics of an HDD System in a Closed Loop Configuration

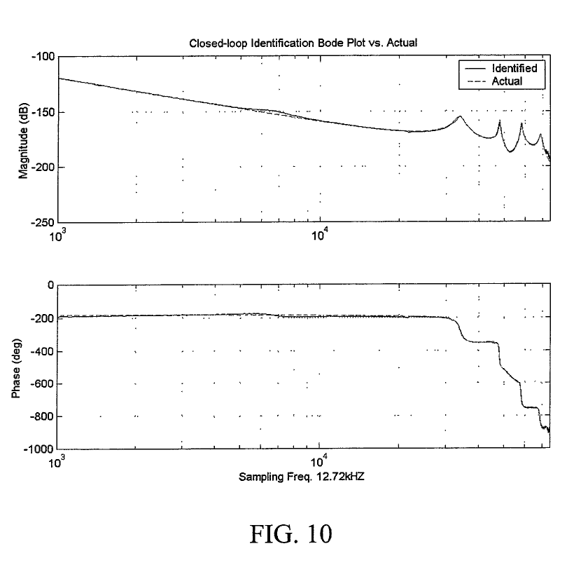

The methods described above for characterizing a system in a closed loop configuration are applied to the HDD system having G(s) as given in example 2. FIG. 10 shows the actual and estimated frequency response values for G(jωᵢ). Table 2 shows a comparison of the actual values and estimated ones for both open loop and closed loop estimation at specific frequency points.

### Example 4

### Signal Reconstruction

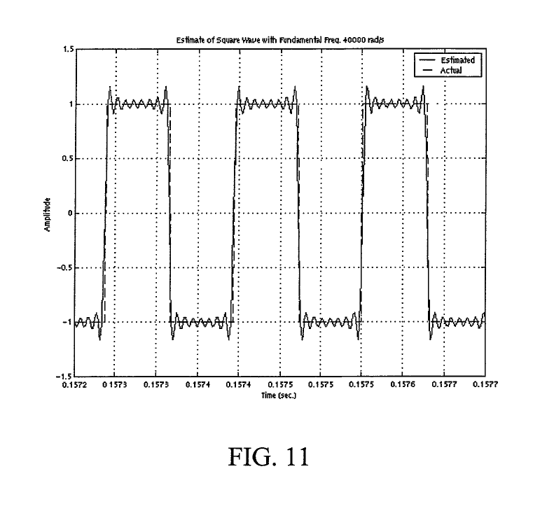

For this exemplary configuration, consider a periodic square wave signal, described as:

$$u ( t ) = \{ \begin{matrix}- 1 , & \text{if} - {T}_{s} / 2 \leq t < 0 \\ 1 , & \text{if} 0 \leq t < {T}_{s} / 2\end{matrix}$$

where Tₛ=0.5π×10⁻⁴ sec is the period of the signal. u(t) is not a band-limited signal. If u(t) is expanded using Fourier series and the first eight terms are taken as an approximation, the following approximation of the square wave u(t) is estimated using the methods described above for signal reconstruction.

$$\hat{u} ( t ) \approx {\sum }_{i = 1}^{8} {\hat{A}}_{( 2 n - 1 )} sin \{ ( 2 n - 1 ) {ω}_{0} t \}$$

where ω₀=40000 (rad/s) is the fundamental frequency of the square wave. The estimate ûf(t) is shown in FIG. 11 together with the actual input.

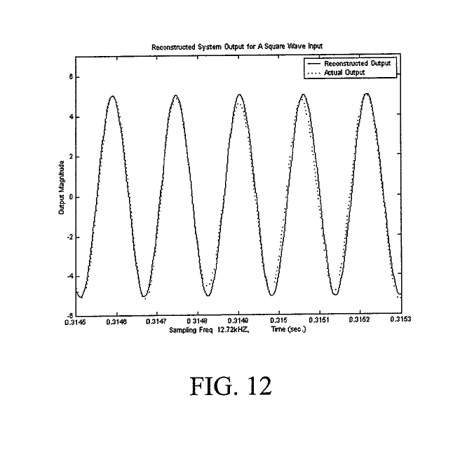

The square wave is an input to the system with transfer function \overline{G}(s) given in example 1. The sampling frequency is ωₛ=12.72 kHz or 79,922.1 (rad/s) which is lower than two times the fundamental frequency of the input to the system and much lower than the higher frequency in the input signal. FIG. 12 shows the actual analog output and the reconstructed one using the method. The small discrepancy shown in the figure is due to the approximation of the square wave as a sum of only eight sinusoids.

What is claimed is:

1. A method of identifying a transfer function for a system, the method comprising:
providing the system with a first and second sinusoidal driving signal, the first driving signal out of phase with the second driving signal;
exciting the system with the first driving signal over a range of frequencies and sampling a measurable system output responsive to the first driving signal to generate a first set of sampled output data;
exciting the system with the second driving signal over the range of frequencies and sampling the measurable system output responsive to the second driving signal to generate a second set of sampled output data; and
determining at least one value of the transfer function from the first and second sets of sampled output data.

2. The method of claim 1, wherein the first driving signal is orthogonal to the second driving signal.

3. The method of claim 2, wherein the step of determining includes forming and solving a linear complex equation.

4. The method of claim 1, wherein the system is characterized by a fixed sampling frequency and wherein the at least one value of the transfer function is at frequency greater than one half of the fixed sampling frequency.

5. The method of claim 1, wherein the at least one value of the transfer function is determined at a frequency characterized by aliasing.

6. A method of identifying a transfer function for a system, the method comprising:
providing the system with a first and second sinusoidal driving signal, the first driving signal out of phase with the second driving signal;
a) exciting the system with the first driving signal over a range of frequencies and sampling a measurable system output responsive to the first driving signal to generate a first set of sampled output data;
b) exciting the system with the second driving signal over a range of frequencies and sampling the measurable system output responsive to the second driving signal to generate a second set of sampled output data;
c) determining a first value of the transfer function from the first and second sets of sampled output data; and
repeating processes a), b) and c) at least once to determine a second value of the transfer function at a frequency different from the first value of the transfer function.

7. The method of claim 6, wherein the first driving signal is orthogonal to the second driving signal.

8. The method of claim 7, wherein the system is characterized by a fixed sampling frequency and wherein the first value of the transfer function is at frequency greater than one half of the fixed sampling frequency.

9. The method of claim 7, wherein the first value of the transfer function is determined at a frequency characterized by aliasing.

10. A method of identifying a transfer function for a system, the method comprising:
providing the system with a first and second sinusoidal driving signal, the first driving signal out of phase with the second driving signal;
providing the system with a filter having zeros corresponding to poles of the system,
passing the first driving signal through the filter and exciting the system with the filtered first driving signal over a range of frequencies and sampling a measurable system output responsive to the first driving signal to generate a first set of sampled output data;
passing the second driving signal through the filter and exciting the system with the filtered second driving signal over a range of frequencies and sampling the measurable system output responsive to the filtered second driving signal to generate a second set of sampled output data; and
determining at least one value of the transfer function from the first and second sets of sampled output data.

11. A method of identifying a transfer function for a system, the method comprising:
providing the system with a first and second sinusoidal driving signal, the first driving signal out of phase with the second driving signal;
providing the system with a filter having a filter response function such that a product of the transfer function and the filter response function has bounded values;
passing the first driving signal through the filter and exciting the system with the filtered first driving signal over a range of frequencies and sampling a measurable system output responsive to the first driving signal to generate a first set of sampled output data;
passing the second driving signal through the filter and exciting the system with the filtered second driving signal over a range of frequencies and sampling the measurable system output responsive to the filtered second driving signal to generate a second set of sampled output data; and
determining at least one value of the transfer function from the first and second sets of sampled output data.

12. The method of claim 11, wherein the first driving signal is orthogonal to the second driving signal.

13. The method of claim 12, wherein the system is characterized by a fixed sampling frequency and wherein the at least one value of the transfer function is at frequency greater than one half of the fixed sampling frequency.

14. The method of claim 11, wherein the at least one value of the transfer function is determined at a frequency characterized by aliasing.

15. A method of identifying a transfer function for a hard disk drive system characterized by a fixed sampling frequency and further characterized by a closed loop configuration, the method comprising:
providing the system with a first and second sinusoidal driving signal, the first driving signal orthogonal to the second driving signal;
a) exciting the system with the first driving signal over a range of frequencies and sampling a measurable system output responsive to the first driving signal to generate a first set of sampled output data;
b) exciting the system with the second driving signal over a range of frequencies and sampling the measurable system output responsive to the second driving signal to generate a second set of sampled output data;
c) determining a first value of the transfer function from the first and second sets of sampled output data; and
repeating processes a), b) and c) at least once to determine a second value of the transfer function at a frequency different from the first value of the transfer function.

16. The method of claim 15, wherein the first value of the transfer function is at a frequency greater than one half of the fixed sampling frequency.

17. The method of claim 15, further comprising tuning a hard disk drive controller in response to the first and second values of the transfer function.

18. The method of claim 15, further comprising providing the system with a filter and passing the first driving signal through the filter before exciting the system with the first driving signal.

19. The method of claim 18, wherein the filter has a filter response function such that a product of the transfer function and the filter response function has bounded values.

20. The method of claim 18, wherein the filter has a filter response function having zeros corresponding to poles of the system,
